(19) United States
(12) Patent Application Publication
(10) Pub. No.: US 2022/0130345 A1
(43) Pub. Date: Apr. 28, 2022

(54) DISPLAY DEVICE, METHOD FOR DRIVING SAME AND VEHICLE

(71) Applicants: BEIJING BOE TECHNOLOGY DEVELOPMENT CO., LTD., Beijing (CN); BOE TECHNOLOGY GROUP CO., LTD., Beijing (CN)

(72) Inventor: Kairan Liu, Beijing (CN)

(73) Assignees: BEIJING BOE TECHNOLOGY DEVELOPMENT CO., LTD.; BOE TECHNOLOGY GROUP CO., LTD.

(21) Appl. No.: 17/325,339

(22) Filed: May 20, 2021

(30) Foreign Application Priority Data
Oct. 28, 2020 (CN) 202011176060.0

(51) Int. Cl. G09G 3/38; G09G 3/00

(52) U.S. Cl. CPC G09G 3/38; G09G 3/002; G09G 2300/0426; G09G 2330/021; G09G 2320/0626; G09G 2380/10; G09G 2360/145

(57) ABSTRACT

A display device is provided. An electrochromic assembly is attached to a light-exiting surface of a display panel in the display device. An electrochromic unit in the electrochromic assembly is driven by a drive circuit to present a specular state or transmit external environment light. When the electrochromic unit transmits external environment light, the display device displays an image normally. When the electrochromic unit presents a specular state, the display device is used as a mirror to present an image of an object.

This application is based on and claims priority to Chinese Patent Application No. 202011176060.0, filed on Oct. 28, 2020 and titled “DISPLAY DEVICE AND VEHICLE,” the disclosure of which is incorporated herein by reference in its entirety.

### TECHNICAL FIELD

The present disclosure relates to the field of display technologies, and in particular a display device, a method for driving the same, and a vehicle.

### BACKGROUND

Organic light emitting diode (OLED) display panels have been widely applied owing to characteristics such as self-luminescence, low drive voltage, and fast response.

In related arts, an OLED display panel can display an image.

### SUMMARY

The present disclosure provides a display device, a method for driving the same, and a vehicle.

In one aspect, a display device is provided. The display device includes: a display panel; an electrochromic assembly, attached to a tight-exiting surface of the display panel, and including at least one electrochromic unit; and at least one drive circuit corresponding to the at least one electrochromic unit respectively, wherein each drive circuit is connected to one corresponding electrochromic unit, and is configured to drive the electrochromic unit to be in one of the following states: presenting a specular state, or transmitting external environment light.

In some embodiments, an orthographic projection of the at least one drive circuit on the display panel is not overlapped with an orthographic projection of the electrochromic assembly on the display panel.

In some embodiments, the electrochromic unit includes: a first electrode, a second electrode, and an electrolyte disposed between the first electrode and the second electrode; wherein the drive circuit is separately connected to the first electrode and the second electrode, and the drive circuit is configured to supply a first power signal to the first electrode and supply a second power signal to the second electrode; and ions in the electrolyte are in one of the following states under action of the first power signal and the second power signal: moving, and remaining stationary.

In some embodiments, the first electrode and the second electrode are both transparent conductive glass coated with fluorine-doped tin oxide that has not been modified with titanium dioxide, and a material of the electrolyte includes silver nitrate; wherein silver ions in the silver nitrate are in one of the following states under action of the first power signal and the second power signal: moving toward the first electrode, moving toward the second electrode, and remaining stationary.

In some embodiments, a potential of the first power signal is higher than a potential of the second power signal; and the silver ions move toward the second electrode under action of the first power signal and the second power signal.

In some embodiments, the first electrode and the second electrode are both transparent conductive glass coated with fluorine-doped tin oxide that has not been modified with titanium dioxide, and the silver ions move toward the second electrode, such that the electrochromic unit presents a specular state.

In some embodiments, the first electrode is transparent conductive glass coated with fluorine-doped tin oxide that has not been modified with titanium dioxide, the second electrode is titanium dioxide-modified transparent conductive glass coated with fluorine-doped tin oxide, and the silver ions move toward the second electrode, such that the electrochromic unit absorbs external environment light.

In some embodiments, the potential of the first power signal is lower than the potential of the second power signal; and the silver ions move toward the first electrode under action of the first power signal and the second power signal.

In some embodiments, the first electrode is transparent conductive glass coated with fluorine-doped tin oxide that has not been modified with titanium dioxide, and the silver ions move toward the first electrode, such that the electrochromic unit presents a specular state.

In some embodiments, the potential of the first power signal is equal to the potential of the second power signal; and the silver ions remain stationary under action of the first power signal and the second power signal, such that the electrochromic unit transmits external environment light.

In some embodiments, the display panel includes a first area, a second area surrounding the first area, and a third area surrounding the second area; and the at least one electrochromic unit includes: at least one first-type electrochromic unit, at least one second-type electrochromic unit, and at least one third-type electrochromic unit; wherein an orthographic projection of the at least one first-type electrochromic unit on the display panel is within the first area, an orthographic projection of the at least one second-type electrochromic unit on the display panel is within the second area, and an orthographic projection of the at least one third-type electrochromic unit on the display panel is within the third area.

In some embodiments, the first electrode is closer to the light-existing surface of the display panel than the second electrode is; a first-type drive circuit in the at least one drive circuit is configured to supply the first power signal to the first electrode in the first-type electrochromic unit and supply the second power signal to the second electrode in the first-type electrochromic unit within a first time period; a second-type drive circuit in the at least one drive circuit is configured to supply the first power signal to the first electrode in the second-type electrochromic unit and supply the second power signal to the second electrode in the second-type electrochromic unit within a second time period; and a third-type drive circuit in the at least one drive circuit is configured to supply the first power signal to the first electrode in the third-type electrochromic unit and supply the second power signal to the second electrode in the third-type electrochromic unit within a third time period, wherein the duration of the third time period is greater than the duration of the second time period, and the duration of the second time period is greater than the duration of the first time period.

In some embodiments, the first electrode and the second electrode are both transparent conductive glass coated with fluorine-doped tin oxide that has not been modified with titanium dioxide, and the potential of the first power signal is different from the potential of the second power signal.

In some embodiments, the first electrode is transparent conductive glass coated with fluorine-doped tin oxide that has not been modified with titanium dioxide, the second electrode is titanium dioxide-modified transparent conductive glass coated with fluorine-doped tin oxide, and the potential of the first power signal s lower than the potential of the second power signal.

In some embodiments, the display panel comprises a first area and a second area disposed on a side of the first area; the at least one electrochromic unit includes: at least one first-type electrochromic unit and at least one second-type electrochromic unit; and an orthographic projection of the at least one first-type electrochromic unit on the display panel is within the first area, and an orthographic projection of the at least one second-type electrochromic unit on the display panel is within the second area.

In some embodiments, the potential of the first power signal supplied by a first-type driving circuit in the at least one driving circuit to the first electrode of the first-type electrochromic unit is lower than the potential of the second power signal supplied to the second. electrode of the first-type electrochromic unit; and the potential of the first power signal supplied by a second-type drive circuit in the at least one drive circuit to the first electrode of the second-type electrochromic unit is equal to the potential of the second power signal supplied to the second electrode of the second-type electrochromic unit.

In some embodiments, the display device further includes a control circuit; wherein the control circuit is connected to each driving circuit, and is configured to supply a first control signal, a second control signal or a third control signal to the driving circuit; and the drive circuit is configured to: drive the electrochromic unit based on the first control signal to present a specular state; drive the electrochromic unit based on the second control signal to absorb external environment light; and drive the electrochromic unit based on the third control signal to transmit external environment light.

In some embodiments, the display device further includes a plurality of light intensity sensors connected to the control circuit; the light intensity sensors are configured to detect the light intensity of external environment light; and the control circuit is configured to: supply the second control signal to the drive circuit if the light intensity is greater than or equal to a light intensity threshold; and supply the third control signal to the drive circuit if the light intensity is less than the light intensity threshold.

In some embodiments, the electrochromic unit includes a transflective film, a first electrode, a liquid crystal layer, a second electrode, and a polarizer sequentially stacked in a direction away from the display panel; wherein the drive circuit is separately connected to the first electrode and the second electrode, and is configured to supply a power signal to the first electrode and the second electrode; the polarizer is configured to adjust external environment light into polarized light; liquid crystal molecules in the liquid crystal layer are configured to tilt under action of the power signal; and the transflective film is configured to transmit the polarized light or reflect the polarized light.

In some embodiments, the display panel is an organic light emitting diode (OLED) display panel or a liquid crystal display (LCD) panel.

In another aspect, a method for driving a display device is provided. The display device includes: a display panel; an electrochromic assembly, wherein the electrochromic assembly is attached to a light-exiting surface of the display panel, and comprises at least one electrochromic unit; and at least one drive circuit corresponding to the at least one electrochromic unit respectively. Each drive circuit is connected to one corresponding electrochromic unit.

The method includes: supplying a power signal to the corresponding electrochromic unit by the drive circuit to drive the electrochromic unit to be in one of the following states: presenting a specular state, and transmitting external environment light.

In still another aspect, a vehicle is provided. The vehicle includes a vehicle body, and a vehicle-mounted rear-view mirror disposed on the vehicle body. The vehicle-mounted rear-view mirror includes a display device.

The display device includes: a display panel; an electrochromic assembly, attached to a light-exiting surface of the display panel, and including at least one electrochromic unit; and at least one drive circuit corresponding to the at least one electrochromic unit respectively, wherein each drive circuit is connected to one corresponding electrochromic unit, and is configured to drive the electrochromic unit to be in one of the following states: presenting a specular state, and transmitting external environment light.

### BRIEF DESCRIPTION OF THE DRAWINGS

For clearer descriptions of the technical solutions in the embodiments of the present disclosure, the following briefly introduces the accompanying drawings required for describing the embodiments. Apparently, the accompanying drawings in the following description show merely some embodiments of the present disclosure, and persons of ordinary skill in the art may still derive other drawings from these accompanying drawings without creative efforts.

FIG. 1 is a schematic structural diagram of a display device according to an embodiment of the present disclosure;

FIG. 2 is a top view of an electrochromic assembly shown in FIG. 1;

FIG. 3 is a schematic structural diagram of an electrochromic unit and a display panel according to an embodiment of the present disclosure;

FIG. 4 is a schematic structural diagram of another electrochromic unit and display panel according to an embodiment of the present disclosure;

FIG. 5 is a schematic structural diagram of still another electrochromic unit and display panel according to an embodiment of the present disclosure;

FIG. 6 is a schematic structural diagram of a display panel according to an embodiment of the present disclosure;

FIG. 7 is a schematic structural diagram of an electrochromic assembly according to an embodiment of the present disclosure;

FIG. 8 is a schematic diagram of a relationship between potential and time according to an embodiment of the present disclosure;

FIG. 9 is a schematic structural diagram of another display panel according to an embodiment of the present disclosure;

FIG. 10 is a schematic structural diagram of another electrochromic assembly according to an embodiment of the present disclosure;

FIG. 11 is a schematic diagram of the effect of a display device according to an embodiment of the present disclosure;

FIG. 12 is a schematic structural diagram of another display device according to an embodiment of the present disclosure;

FIG. 13 is a schematic structural diagram of another electrochromic unit and display panel according to an embodiment of the present disclosure;

FIG. 14 is a flowchart of a method for driving a display device according to an embodiment of the present disclosure;

FIG. 15 is a schematic structural diagram of a vehicle according to an embodiment of the present disclosure;

FIG. 16 is a schematic diagram of the effect of another display device according to an embodiment of the present disclosure;

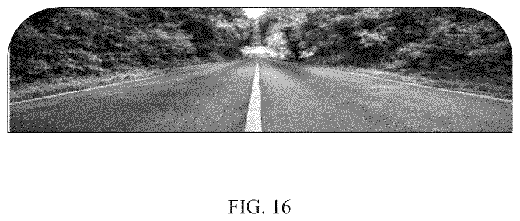

FIG. 17 is a schematic diagram of the effect of still another display device according to an embodiment of the present disclosure; and

FIG. 18 is a schematic diagram of the effect of yet another display device according to an embodiment of the present disclosure.

### DETAILED DESCRIPTION

For clearer descriptions of the objectives, technical solutions, and advantages of the present disclosure, embodiments of the present disclosure are described in detail hereinafter with reference to the accompanying drawings.

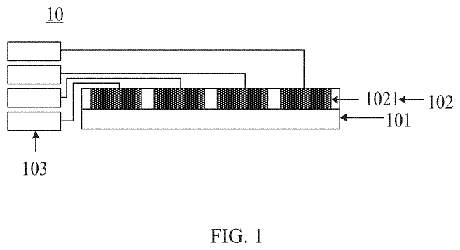

FIG. 1 is a schematic structural diagram of a display device according to an embodiment of the present disclosure. As can be seen from FIG. 1, a display device 10 includes a display panel 101, an electrochromic assembly 102, and at least one drive circuit 103. The electrochromic assembly 102 is attached to a light-exiting surface of the display panel 101. Referring to FIG. 1, the electrochromic assembly 102 includes at least one electrochromic unit 1021.

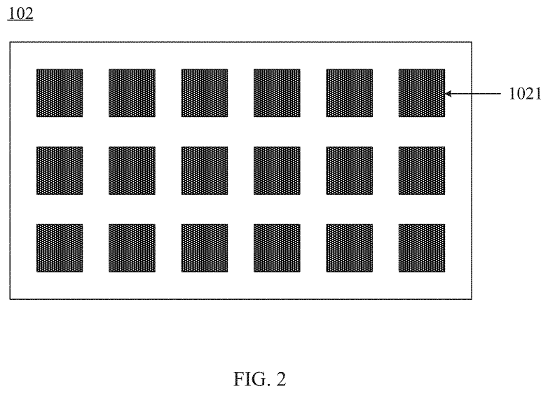

FIG. 2 is a top view of an electrochromic assembly shown in FIG. 1. As can be seen from FIG. 2, the electrochromic assembly 102 may include a plurality of electrochromic units 1021. Eighteen electrochromic units 1021 are shown in FIG. 2.

The at least one electrochromic unit 1021 corresponds to the at least one drive circuit 103 respectively. Each drive circuit 103 is connected to one corresponding electrochromic unit 1021, and is configured to drive the electrochromic unit 1021 to be in one of the following states: presenting a specular state, and transmitting external environment light.

In the embodiments of the present disclosure, the drive circuit 103 supplies a power signal to one corresponding electrochromic unit 1021, and the electrochromic unit 1021 adjusts its own state under action of the power signal, such that the display device 10 achieves different display effects.

For example, if the electrochromic unit 1021 presents a specular state, the electrochromic unit 1021 may be used as a mirror to present an image of an object, and a user cannot see an image displayed by the display panel 101 through the electrochromic unit 1021. If the electrochromic unit 1021 transmits external environment light (that is, the electrochromic unit 1021 presents a non-opaque state), the user can see the image displayed by the display panel 101 through the electrochromic unit 1021.

In summary, this embodiment of the present disclosure provides a display device. An electrochromic assembly is attached to a light-exiting surface of a display panel in the display device. An electrochromic unit in the electrochromic assembly is driven by the drive circuit to present a specular state or transmit external environment light. When the electrochromic unit. transmits external environment light, the display device displays an image normally. When the electrochromic unit presents a specular state, the display device is used as a mirror to present an image of an object. That is, the display device may display an image and may be used as a mirror, to achieve relatively high flexibility.

In the embodiments of the present disclosure, referring to FIG. 1, an orthographic projection of the at least one drive circuit 103 on the display panel 101 may not be overlapped with an orthographic projection of the electrochromic assembly 102 on the display panel 101, to prevent the drive circuit 103 from blocking the electrochromic assembly 102, and to avoid affecting the display effect of the display device.

In some embodiments, the display panel 101 may be an organic light emitting diode (OLED) display panel or may be a liquid crystal display (LCD) panel.

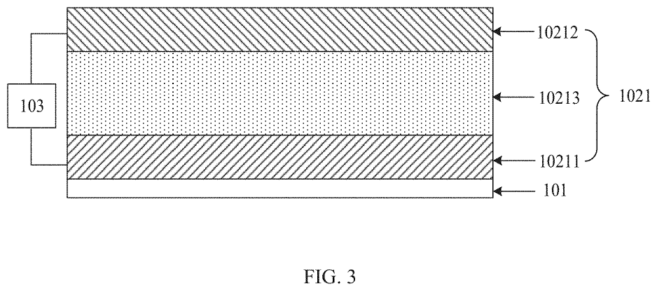

FIG. 3 is a schematic structural diagram of an electrochromic unit and a display panel according to an embodiment of the present disclosure. Referring to FIG, 3, the electrochromic unit 1021 may include: a first electrode 10211, a second electrode 10212, and an electrolyte 10213 disposed between the first electrode 10211 and the second electrode 10212. The drive circuit 103 may be separately connected to the first electrode 10211 and the second electrode 10212. The drive circuit 103 may be configured to supply a first power signal to the first electrode 10211 and supply a second power signal to the second electrode 10212. Ions in the electrolyte 10213 may move or remain stationary under action of the first power signal and the second power signal.

In some embodiments, the first electrode 10211 and the second electrode 10212 may both be transparent conductive glass coated with fluorine (F)-doped tin oxide (SnO₂) that has not been modified with titanium dioxide (TiO₂) ((SnO₂:F), FTO). The material of the electrolyte 10213 may include silver nitrate (AgNO₃).

Silver ions (Ag+) in the sifter nitrate may move toward the first electrode 10211 under action of the first power signal and the second power signal, or move toward the second electrode 10212, or remain stationary. In this way, the electrochromic unit 1021 may be caused to present different states.

In some embodiments, the silver ions in the silver nitrate move toward the first electrode 10211, and are deposited on the first electrode 10211, to form a deposited layer of the silver ions (mirror) on a side of the first electrode 10211 proximal to the second electrode 10212. In this case, the electrochromic unit 1021 presents a specular state. Alternatively, the silver ions in the silver nitrate move toward the second electrode 10212, and are deposited on the second electrode 10212, to form a deposited layer of the silver ions (mirror) on a side of the second electrode 10212 proximal to the first electrode 10211. In this case, the electrochromic unit 1021 presents a specular state. Further alternatively, the silver ions in the silver nitrate remain stationary, that is, suspended between the first electrode 10211 and the second electrode 10212. In this case, the electrochromic unit 1021 transmits external environment light (presents a non-opaque state).

In some embodiments, the first electrode 10211 may be transparent conductive glass coated with fluorine-doped tin oxide that has not been modified with titanium dioxide. The second electrode 10212 is titanium dioxide-modified transparent conductive glass coated with fluorine-doped tin oxide. The material of the electrolyte 10213 may include silver nitrate.

In some embodiments, the silver ions in the silver nitrate move toward the first electrode 10211, and are deposited on the first electrode 10211, such that the deposited layer of the silver ions (mirror) are formed on the side of the first electrode 10211 proximal to the second electrode 10212. In this case, the electrochromic unit 1021 presents a specular state. Alternatively, the silver ions in the silver nitrate move toward the second electrode 10212, and are deposited on the second electrode 10212, such that the deposited layer of the silver ions are formed on the side of the second electrode 10212 proximal to the first electrode 10211. In this case, the electrochromic unit 1021 absorbs external environment light (presents a black state). Further alternatively, the silver ions in the silver nitrate remain stationary, that is, are suspended between the first electrode 10211 and the second electrode 10212. In this case, the electrochromic unit 1021 transmits external environment light (presents a non-opaque state).

In some embodiments, the electrolyte may further include tetrabutylammonium bromide (TBABr) and copper chloride (CuCl₂).

In some embodiments, a potential of the first power signal supplied by the drive circuit 103 to the first electrode 10211 is higher than a potential of the second power signal supplied by the drive circuit 103 to the second electrode 10212. Silver ions a1 may move toward the second electrode 10212 with relatively low potential under action of the first power signal and the second power signal, and are deposited on the second electrode 10212.

If the second electrode 10212 is transparent conductive glass coated with fluorine-doped tin oxide that has not been modified with titanium dioxide, the silver ions are deposited on the second electrode 10212 such that the electrochromic unit 1021 presents a specular state. If the second electrode 10212 is titanium dioxide-modified transparent conductive glass coated with fluorine-doped tin oxide, the silver ions are deposited on the second electrode 10212 such that the electrochromic unit 1021 absorbs external environment light.

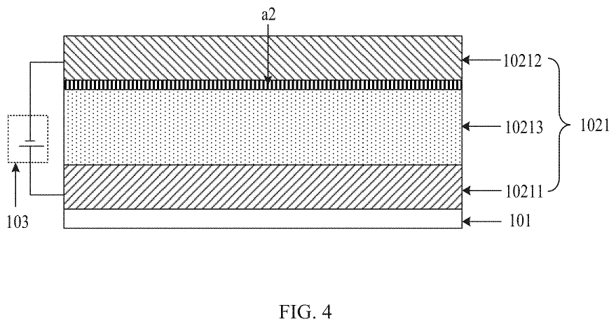

In some embodiments, the potential of the second power signal may be negative potential, and the potential of the first power signal may be zero potential or positive potential. Referring to FIG. 4, the drive circuit may be a battery. The negative electrode of the battery may be connected to the second electrode 10212, and the positive electrode of the battery may be connected to the first electrode 10211. Because the silver ions in the silver nitrate of the electrolyte 10213 are positively charged, the silver ions may usually move toward the second electrode 10212 (negatively charged) connected to the negative electrode, and a deposited layer a2 of the silver ions is formed on the side of the second electrode 10212 proximal to the first electrode 10211.

In some embodiments, the potential of the first power signal may be 2.5 V, and the potential of the second power signal may be −2.5 V.

In some embodiments, the potential of the first power signal supplied by the drive circuit 103 to the first electrode 10211 is lower than the potential of the second power signal supplied by the drive circuit 103 to the second electrode 10212. The silver ions may move toward the first electrode 10211 with relatively low potential under action of the first power signal and the second power signal, and are deposited on the first electrode 10211.

In addition, because the first electrode 10211 is transparent conductive glass coated with fluorine-doped tin oxide that has not been modified with titanium dioxide, the silver ions are deposited on the first electrode 10211 such that the electrochromic unit 1021 presents a specular state.

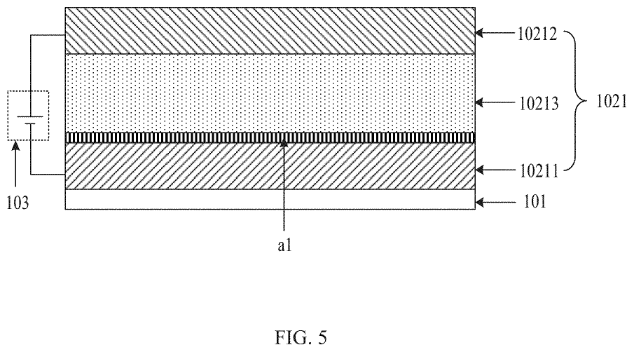

In some embodiments, the potential of the first power signal may be negative potential, and the potential of the second power signal may be zero potential or positive potential. Referring to FIG. 5, the drive circuit may be a battery, the negative electrode of the battery may be connected to the first electrode 10211, and the positive electrode of the battery may be connected to the second electrode 10212. Because the silver ions in the silver nitrate of the electrolyte 10213 are positively charged, the silver ions may move toward the first electrode 10211 (negatively charged) connected to the negative electrode, and a deposited layer a1 of the silver ions is formed on the side of the first electrode 10211 proximal to the second electrode 10212.

In some embodiments, the potential of the first power signal may be −2.5 V (volts), and the potential of the second power signal may be 0 V.

In some embodiments, the potential of the first power signal supplied by the drive circuit 103 to the first electrode 10211 is equal to the potential of the second power signal supplied by the drive circuit 103 to the second electrode 10212. The silver ions remain stationary under action of the first power signal and the second power signal, that is, are suspended between the first electrode 10211 and the second electrode 10212. In this case, the electrochromic unit 1021 may transmit external environment light, that is, the electrochromic unit 1021 is in a non-opaque state.

Because the potential of the first power signal is equal to the potential of the second power signal, the silver ions do not move and are present in the electrolyte 10213 in the form of silver nitrate. For example, the potential of the first power signal and the potential of the second power signal may both be 0 V.

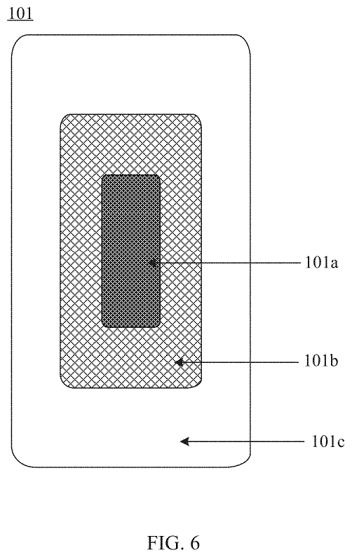

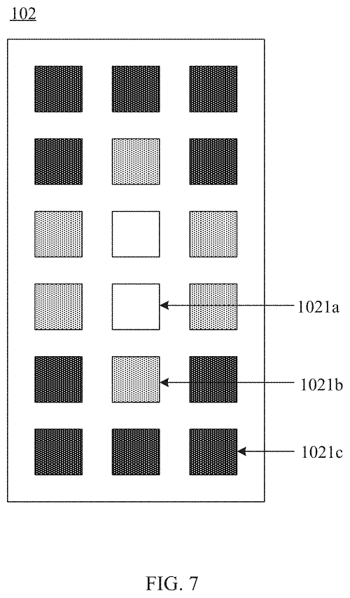

FIG. 6 is a schematic structural diagram of a display panel according to an embodiment of the present disclosure. As can be seen from FIG. 6, the display panel 101 may have a first area 101a, a second area 101b surrounding the first area 101a, and a third area 101c surrounding the second area 101b . In addition, referring to FIG. 7, the at least one electrochromic unit 1021 may include: at least one first-type electrochromic unit 1021a, at least one second-type electrochromic unit 1021b, and at least one third-type electrochromic unit 1021c.

An orthographic projection of the at least one first-type electrochromic unit 1021a on the display panel 101 may be within the first area 101a. An orthographic projection of the at least one second-type electrochromic unit 1021b on the display panel 101 may be within the second area 101b. An orthographic projection of the at least one third-type electrochromic unit 1021c on the display panel 101 may be within the third area 101c.

In some embodiments, referring to FIG. 7, the at least one electrochromic unit 1021 may include two first-type electrochromic units 1021a, six second-type electrochromic units 1021b, and ten third-type electrochromic units 1021b.

In the embodiments of the present disclosure, the drive circuit 103 connected to the first-type electrochromic unit 1021a is a first-type drive circuit. The drive circuit 103 connected to the second-type electrochromic unit 1021b is a second-type drive circuit. The drive circuit 103 connected to the third-type electrochromic unit 1021c is a third-type drive circuit.

The first-type drive circuit is configured to supply the first power signal to the first electrode 10211 in the first-type electrochromic unit 1021a and supply the second power signal to the second electrode 10212 in the first-type electrochromic unit 1021a within a first time period. The second-type drive circuit 103 is configured to supply the first power signal to the first electrode 10211 in the second-type electrochromic unit 1021b and supply the second power signal to the second electrode 10212 in the second-type electrochromic unit 1021b within a second time period. The third-type drive circuit 103 is configured to supply the first power signal to the first electrode 10211 in the third-type electrochromic unit 1021c and supply the second power signal to the second electrode 10212 in the third-type electrochromic unit 1021c within a third time period.

As can be seen from the foregoing first implementation to third implementation, to cause the electrochromic unit 1021 to present a specular state, the potential of the first power signal supplied by the drive circuit 103 to transparent conductive glass coated with fluorine-doped tin oxide that has not been modified with titanium dioxide should be lower than the potential of the second power signal supplied to another electrode. That is, the silver ions may be caused to move toward transparent conductive glass coated with fluorine-doped tin oxide that has not been modified with titanium dioxide.

It is assumed that the first electrode 10211 and the second electrode 10212 are both transparent conductive glass coated with fluorine-doped tin oxide that has not been modified with titanium dioxide. The silver ions may be caused to move toward the first electrode 10211, or the silver ions may be caused to move toward the second electrode 10212.

In this way, the potential of the first power signal supplied by the drive circuit 103 to the first electrode 10211 may be lower than the potential of the second power signal supplied to the second electrode 10212. Alternatively, the potential of the second power signal supplied by the drive circuit 103 to the second electrode 10212 may be lower than the potential of the first power signal supplied to the first electrode 10211.

If the potential of the first power signal pro supplied vided by the drive circuit 103 to the first electrode 10211 is lower than the potential of the second power signal supplied to the second electrode 10212, the silver ions may move toward the first electrode 10211, and are deposited on the first electrode 10211. In this case, the side of the first electrode 10211 proximal to the second electrode 10212, in the electrochromic unit 1021 may present a specular state. Alternatively, if the potential of the second power signal supplied by the drive circuit 103 to the second electrode 10212 is lower than the potential of the first power signal supplied to the first electrode 10211, the silver ions may move toward the second electrode 10212, and are deposited on the second electrode 10212. In this case, the side of the second electrode 10212 proximal to the first electrode 10211, in the electrochromic unit 1021 may present a specular state.

It is assumed that the first electrode 10211 is transparent conductive glass coated with fluorine-doped tin oxide that has not been modified with titanium dioxide and the second electrode 10212 is titanium dioxide-modified transparent conductive glass coated with fluorine-doped tin oxide, the silver ions may be caused to move toward the first electrode 10211.

In this way, the potential of the first power signal supplied by the drive circuit 103 to the first electrode 10211 may be lower than the potential of the second power signal supplied to the second electrode 10212. In this case, the silver ions move toward the first electrode 10211, and are deposited on the first electrode 10211. The side, proximal to the second electrode 10212, of the first electrode 10211 in the electrochromic unit 1021 may present a specular state.

If the potential of the second power signal supplied by the drive circuit 103 to the second electrode 10212 is lower than the potential of the first power signal supplied to the first electrode 10211, in this case, the silver ions move toward the second electrode 10212, and are deposited on the second electrode 10212. Because the second electrode 10212 is titanium dioxide-modified transparent conductive glass coated with fluorine-doped tin oxide, the electrochromic unit 1021 cannot present a specular state.

In this way, regardless of whether the second electrode 10212 is transparent conductive glass coated with fluorine-doped tin oxide that has not been modified with titanium dioxide or titanium dioxide-modified transparent conductive glass coated with fluorine-doped tin oxide, provided that it is ensured that the potential of the first power signal supplied by the drive circuit 103 to the first electrode 10211 is lower than the potential of the second power signal supplied to the second electrode 10212, the silver ions may be caused to move toward the side proximal to the first electrode 10211 (transparent conductive glass coated with fluorine-doped tin oxide that has not been modified with titanium dioxide). That is, the electrochromic unit 1021 may present a specular state.

In some embodiments, it is assumed that the first electrode 10211 and the second electrode 10212 are both titanium dioxide-modified transparent conductive glass coated with fluorine-doped tin oxide and the potential of the first power signal is lower than the potential of the second power signal. In this case, the silver ions in the first-type electrochromic unit 1021a move toward the first electrode 10211 within the first time period, and are deposited on the first electrode 10211. The silver ions in the second-type electrochromic unit 1021b move toward the first electrode 10211 within the second time period, and are deposited on the first electrode 10211. The silver ions in the third-type electrochromic unit 1021c move toward the first electrode 10211 within the third time period, and are deposited on the first electrode 10211. In addition, because the first electrode 10211 is transparent conductive glass coated with fluorine-doped tin oxide that has not been modified with titanium dioxide, the first-type electrochromic unit 1021a, the second-type electrochromic unit 1021b, and the third-type electrochromic unit 1021c may all present a specular state.

It is assumed that the first electrode 10211 and the second electrode 10212 are both titanium dioxide-modified transparent conductive glass coated with fluorine-doped tin oxide and the potential of the second power signal is lower than the potential of the first power signal, In this way, the silver ions in the first-type electrochromic unit 1021a move toward the second electrode 10212 within the first time period, and are deposited on the second electrode 10212. The silver ions in the second-type electrochromic unit 1021b move toward the second electrode 10212 within the second time period, and are deposited on the second electrode 10212. The silver ions in the third-type electrochromic unit 1021c move toward the second electrode 10212 within the third time period, and are deposited on the second electrode 10212. In addition, because the second electrode 10212 is transparent conductive glass coated with fluorine-doped tin oxide that has not been modified with titanium dioxide, the first-type electrochromic unit 1021a, the second-type electrochromic unit 1021b, and the third-type electrochromic unit 1021c may all present a specular state.

It is assumed that the first electrode 10211 is transparent conductive glass coated with fluorine-doped tin oxide that has not been modified with titanium dioxide, the second electrode 10212 is titanium dioxide-modified transparent conductive glass coated with fluorine-doped tin oxide, and the potential of the first power signal is lower than the potential of the second power signal. In this case, the silver ions in the first-type electrochromic unit 1021a move toward the first electrode 10211 within the first time period, and are deposited on the first electrode 10211. The silver ions in the second-type electrochromic unit 1021b move toward the first electrode 10211 within the second time period, and are deposited on the first electrode 10211. The silver ions in the third-type electrochromic unit 1021c move toward the first electrode 10211 within the third time period, and are deposited on the first electrode 10211. In addition, because the first electrode 10211 is transparent conductive glass coated with fluorine-doped tin oxide that has not been modified with titanium dioxide, the first-type electrochromic unit 1021a, the second-type electrochromic unit 1021b, and the third-type electrochromic unit 1021c may all present a specular state.

The main reason that the electrochromic unit 1021 can present a specular state is that the silver ions are electrically deposited on transparent conductive glass coated with fluorine-doped tin oxide that has not been modified with titanium dioxide. Because the electrical deposition is a process, the thickness of the deposited silver ions is positively correlated with deposition duration. That is, when the deposition duration is longer, the thickness of the deposited silver ions is larger. When the deposition duration is shorter, the thickness of the deposited silver ions is smaller.

In the embodiments of the present disclosure, if the second electrode 10212 is transparent conductive glass coated with fluorine-doped tin oxide that has not been modified with titanium dioxide, the first electrode 10211 is made closer to the light-exiting surface of the display panel 101 than the second electrode 10212 is, and the potential of the first power signal supplied by the drive circuit 103 to the first electrode 10211 may be lower than the potential of the second power signal supplied to the second electrode 10212, such that the electrochromic assembly 102 forms a concave mirror facing the user. Alternatively, the second electrode 10212 is made closer to the light-exiting surface of the display panel 101 than the first electrode 10211 is, and the potential of the second power signal supplied by the drive circuit 103 to the second electrode 10212 is made lower than the potential of the first power signal supplied to the first electrode 10211, such that the electrochromic assembly 102 forms a concave mirror facing the user. In addition, the duration of the third time period should be greater than the duration of the second time period and the duration of the second time period should be greater than the duration of the first time period.

If the second electrode 10212 is titanium dioxide-modified transparent conductive glass coated with fluorine-doped tin oxide, the first electrode 10211 is made closer to the light-exiting surface of the display panel 101 than the second electrode 10212 is, and the potential of the first power signal supplied by the drive circuit 103 to the first electrode 10211 is made lower than the potential of the second power signal supplied to the second electrode 10212, such that the electrochromic assembly 102 forms the concave mirror facing the user. In addition, the duration of the third time period should be greater than the duration of the second time period and the duration of the second time period should be greater than the duration of the first time period.

To be specific, regardless of whether the second electrode 10212 is transparent conductive glass coated with fluorine-doped tin oxide that has not been modified with titanium dioxide or titanium dioxide-modified transparent conductive glass coated with fluorine-doped tin oxide, the first electrode 10211 is made closer to the light-exiting surface of the display panel 101 than the second electrode 10212 is, and the potential of the first power signal supplied by the drive circuit 103 to the first electrode 10211 is made lower than the potential of the second. power signal supplied to the second electrode 10212, such that the electrochromic assembly 102 forms the concave mirror facing the user. In addition, the duration of the third time period should be greater than the duration of the second time period and the duration of the second time period should be greater than the duration of the first time period.

It is assumed that the silver ions are deposited on the first electrode 10211, because the duration of the third time period is greater than the duration of the second time period and the duration of the second time period is greater than the duration of the first time period, the thickness of the silver ions in the third-type electrochromic unit 1021c deposited on the first electrode 10211 is greater than the thickness of the silver ions in the second-type electrochromic unit 1021b deposited on the first electrode 10211, and the thickness of the silver ions in the second-type electrochromic unit 1021b deposited on the first electrode 10211 is greater than the thickness of the silver ions in the first-type electrochromic unit 1021a deposited on the first electrode 10211. In this way, the deposited layer of the silver ions of the plurality of electrochromic units 1021 may gradually become thicker from center to edge, and the deposited layer of the silver ions is disposed on one electrode (for example, the first electrode 10211) proximal to the light-exiting surface of the display panel 101, such that the electrochromic assembly 102 may be caused to form the concave mirror facing the user, the concave mirror can implement the function of partial enlargement.

In some embodiments, it is assumed that the silver ions are deposited on the second electrode 10212, Because the duration of the third time period is greater than the duration of the second time period and the duration of the second time period is greater than the duration of the first time period, the thickness of the silver ions in the third-type electrochromic unit 1021c deposited on the second electrode 10212 is greater than the thickness of the silver ions in the second-type electrochromic unit 1021b deposited on the second electrode 10212, and the thickness of the silver ions in the second-type electrochromic unit 1021b deposited on the second electrode 10212 is greater than the thickness of the silver ions in the first-type electrochromic unit 1021a deposited on the second electrode 10212. In this way, the deposited layer of the silver ions of the plurality of electrochromic units 1021 may gradually become thicker from center to edge, and the deposited layer of the silver ions is disposed on one electrode (for example, the second electrode 10212) proximal to the light-exiting surface of the display panel 101, such that the electrochromic assembly 102 may be caused to form the concave mirror facing the user, and the concave mirror can implement the function of partial enlargement.

To be specific, one electrode proximal to the light-exiting surface of the display panel 101 is transparent conductive glass coated with fluorine-doped tin oxide that has not been modified with titanium dioxide and the potential of a power signal supplied by the drive circuit 103 to one electrode proximal to the light-exiting surface of the display panel 101 is lower than the potential of a power signal supplied to another electrode distal from the light-exiting surface of the display panel 101, such that the electrochromic assembly 102 forms the concave mirror facing the user.

In some embodiments, the first time period, the second time period, and the third time period may have an overlapping area or may have no overlapping area. This is not limited in this embodiment of the present disclosure, as long as the duration of the third time period is greater than the duration of the second time period and the duration of the second time period is greater than the duration of the first time period.

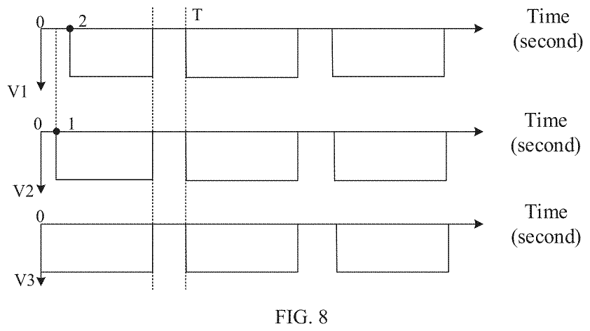

In some embodiments, referring to FIG. 8, the third-type drive circuit 103 supplies a first power signal with a potential V1 of −2.5 V to the first electrode 10211 of the third-type electrochromic unit 1021c. After the duration of one second (s), the second-type drive circuit 103 supplies a first power signal with a potential V2 of −2.5 V to the first electrode 10211 of the second-type electrochromic unit 1021b. After the duration of one second, the first-type drive circuit 103 supplies a first power signal with a potential V3 of −2.5 V to the first electrode 10211 of the first-type electrochromic unit 1021a.

To be specific, the second-type drive circuit 103 is delayed by one second relative to the third-type drive circuit 103 to apply a voltage to the electrochromic unit 1021, in addition, the first-type drive circuit 103 is delayed by one second relative to the second-type drive circuit 103 to apply a voltage to the electrochromic unit 1021.

In some embodiments, various types of drive circuits 103 may supply a second power signal with potential of 0 V to the second electrode 10212 of the electrochromic unit 1027.

As can be seen from FIG. 8, in a process of forming the concave mirror by the electrochromic assembly 102, various drive circuits 103 may supply power signals to the electrochromic unit 1021 within a plurality of separate sub-time periods. Certainly, the various drive circuits 103 may alternatively supply power signals to the electrochromic unit 1021 continuously. This is not limited in this embodiment of the present disclosure.

In addition, if the various drive circuits 103 supply power signals to the electrochromic unit 1021 within a plurality of sub-time periods, after a moment T, the various types of drive circuits 103 may supply power signals to the electrochromic unit 1021 within the sub-time periods for the same duration, to ensure the deposition stability of the silver ions.

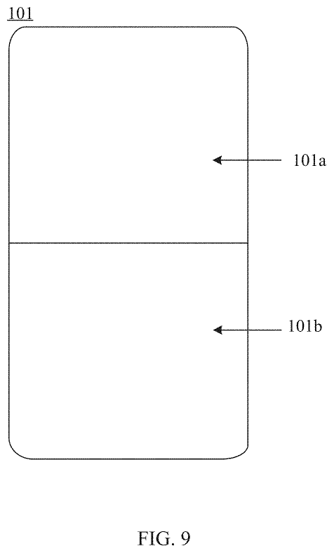

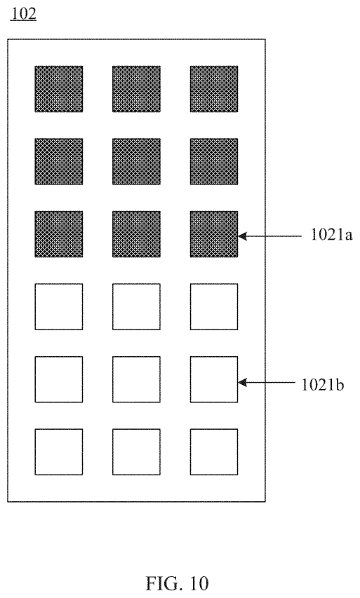

FIG. 9 is a schematic structural diagram of another display panel according to an embodiment of the present disclosure. Referring to FIG. 9, the display panel 101 may include a first area 101a and a second area 101b disposed on a side of the first area 101a. In addition, referring to FIG. 10, the at least one electrochromic unit 1021 may include at least one first-type electrochromic unit 1021a and at least one second-type electrochromic unit 1021b.

An orthographic projection of the at least one first-type electrochromic unit 1021a on the display panel 101 may be within the first area 101a, and an orthographic projection of the at least one second-type electrochromic unit 1021b on the display panel 101 may be within the second area 101b.

In some embodiments, referring to FIG. 10, the at least one electrochromic unit 1021 may include nine first-type electrochromic units 1021a and nine second-type electrochromic units 1021b.

In the embodiments of the present disclosure, the drive circuit 103 connected to the first-type electrochromic unit 1021a is a first-type drive circuit, and the drive circuit 103 connected to the second-type electrochromic unit 1021b is a second-type drive circuit.

The potential of the first power signal supplied by the first-type drive circuit to the first electrode 10211 in the first-type electrochromic unit 1021a may be lower than the potential of the second power signal supplied to the second electrode 10212 in the first-type electrochromic unit 1021a. The potential of the first power signal supplied by the second-type drive circuit to the first electrode 10211 in the second-type electrochromic unit 1021b is equal to the potential of the second power signal supplied to the second electrode 10212 in the second-type electrochromic unit 1021b.

As can be seen from the foregoing first implementation to third implementation, the potential of the first power signal supplied by the first-type drive circuit to the first electrode 10211 in the first-type electrochromic unit 1021a is lower than the potential of the second power signal supplied to the second electrode 10212 in the first-type electrochromic unit 1021a, and the silver ions in the first-type electrochromic unit 1021a may be caused to move toward the first electrode 10211, and are deposited on the first electrode 10211. In addition, because the first electrode 10211 in the first-type electrochromic unit 1021a is transparent conductive glass coated with fluorine-doped tin oxide that has not been modified with titanium dioxide, the first-type electrochromic unit 1021a may present a specular state.

In some embodiments, if the second electrode 10212 is also transparent conductive glass coated with fluorine-doped tin oxide that has not been modified with titanium dioxide, the potential of the second power signal supplied by the first-type drive circuit to the second electrode 10212 in the first-type electrochromic unit 1021a is lower than the potential of the first power signal supplied to the first electrode 10211 in the first-type electrochromic unit 1021a, and the first-type electrochromic unit 1021a may also be caused to present a specular state. In this case, the silver ions in the first-type electrochromic unit 1021a may move toward the second electrode 10212, and are deposited on the second electrode 10212.

In the embodiments of the present disclosure, the potential of the first power signal supplied by the second-type drive circuit to the first electrode 10211 in the second-type electrochromic unit 1021b is equal to the potential of the second power signal supplied to the second electrode 10212 in the second-type electrochromic unit 1021b. In this way, the silver ions in the second-type electrochromic unit 1021b may be caused to remain stationary, and the second-type electrochromic unit 1021bcan transmit external environment light.

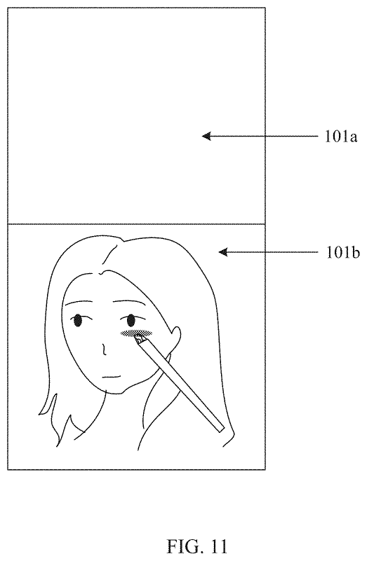

Because the first-type electrochromic unit 1021a presents a specular state and the second-type electrochromic unit 1021b transmits external environment light, a part of the electrochromic assembly 102 may be used as a mirror to present an image of an object, and another part may be configured to transmit an image displayed on the display panel 101. In this way, referring to FIG. 11, the user may use the first area 101a as a mirror and use the second area 101b to view content displayed on the display panel 101, and the display device has relatively high flexibility.

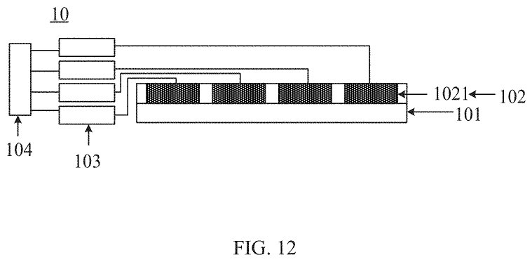

FIG. 12 is a schematic structural diagram of another display device according to an embodiment of the present disclosure. As can be seen from FIG. 12, the display device 10 may further include a control circuit 104. The control circuit 104 may be connected to each drive circuit 103 and may be configured to supply a first control signal, a second control signal or a third control signal to the drive circuit 103.

The drive circuit 103 may be configured to: drive the electrochromic unit 1021 based on the first control signal to present a specular state, drive the electrochromic unit 1021 based on the second control signal to absorb external environment light, and drive the electrochromic unit 1021 based on the third control signal to transmit external environment light.

The drive circuit 103 may include a signal detector. The signal detector may determine, based on a control signal that is transmitted by the control circuit 104 and is received. by the drive circuit 103, whether the received control signal is the first control signal, the second control signal, or the third control signal. The drive circuit 103 may further drive the electrochromic unit 1021 based on the determined control signal.

In the embodiments of the present disclosure, the display device 10 may further include a plurality of light intensity sensors (not shown in the figure) connected to the control circuit 104. The light intensity sensors may be configured to detect the light intensity of external environment light. In addition, the plurality of light intensity sensors may be evenly distributed on a side, distal from the display panel 101, of the electrochromic assembly 102, to detect the light intensity of environment light in different areas of the display device.

When external environment light is relatively weak, the external environment light has relatively low impact on the display effect of the display panel 101. Therefore, the electrochromic unit 1021 may be caused to transmit external environment light, to ensure that the display panel 101 has an optimal light extraction efficiency, to ensure the display effect of the display panel 101. In addition, due to external environment light is relatively intense, the external environment light significantly affects the display effect of the display panel 101. Therefore, the electrochromic unit 1021 may be caused to absorb external environment light, to reduce the impact of external environment light on the display effect of the display panel 101.

In some embodiments, the control circuit 104 may include a light intensity comparator, and the light intensity comparator may pre-store a light intensity threshold, The light intensity comparator may compare the light intensity of external environment light detected by the light intensity sensors with the light intensity threshold. When the light intensity comparator determines that the light intensity of external environment light is greater than or equal to the light intensity threshold, the control circuit 104 may supply the second control signal to the drive circuit 103, such that the drive circuit 103 drives the electrochromic unit 1021 based on the second control signal to absorb external environment light. When the light intensity comparator determines that the light intensity of external environment light detected by the light intensity sensors is less than the light intensity threshold, the control circuit 104 may supply the third control signal to the drive circuit 103, such that the drive circuit 103 drives the electrochromic unit 1021 based on the third control signal to transmit external environment light.

In the embodiments of the present disclosure, because each electrochromic unit 1021 in the electrochromic assembly 102 corresponds to one drive circuit 103, the control circuit 104 may control the drive circuit based on the light intensity detected by the light intensity sensors in different areas to adjust the states of the electrochromic unit 1021 in the different areas.

For example, when the light intensity comparator determines that light intensity detected by the light intensity sensors disposed in an area of the electrochromic assembly 102 is greater than or equal to the light intensity threshold, the control circuit 104 may supply the second control signal to the drive circuit 103 corresponding to the electrochromic unit 1021 in the area. Alternatively, when the light intensity comparator determines that light intensity detected by the light intensity sensors disposed in an area of the electrochromic assembly 102 is less than the light intensity threshold, the control circuit 104 can supply the third control signal to the drive circuit 103 corresponding to the electrochromic unit 1021 in the area.

In the embodiments of the present disclosure, when more electrochromic units 1021 absorb external environment light in the electrochromic assembly 102, the light extraction efficiency of the display panel 101 is lower. Therefore, when the light intensity of external environment light is relatively high, such that the light extraction efficiency of the display panel 101 is ensured, and only some electrochromic units 1021 may be caused to absorb external environment light. For example, 50% of the electrochromic units 1021 in the electrochromic assembly 102 absorb external environment light and the 50% of the electrochromic units 1021 are evenly distributed, such that external environment light can be prevented from affecting the display effect of the display panel 101 and the light extraction efficiency of the display panel 101 can be ensured.

In some embodiments, when the electrochromic unit 1021 absorbs external environment light, a black state may be presented. Therefore, the electrochromic unit 1021 may be used as a black matrix layer in the display panel 101, such that the structure of the display panel 101 can be simplified.

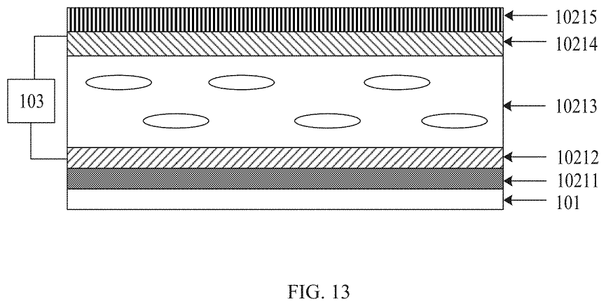

FIG. 13 is a schematic structural diagram of another electrochromic unit and display panel according to an embodiment of the present disclosure. Referring to FIG. 13, the electrochromic unit 1021 may include a transflective film 10211, a first electrode 10212, a liquid crystal layer 10213, a second electrode 10214, and a polarizer 10215 that are sequentially stacked in a direction away from the display panel 101.

The drive circuit 103 may be separately connected to the first electrode 10212 and the second electrode 10214, and may be configured to supply power signals to the first electrode 10212 and the second electrode 10214. The polarizer 10215 may be configured to adjust external environment light into polarized light. Liquid crystal molecules in the liquid layer 10213 may tilt under action of the power signal supplied by the drive circuit 103. The transflective film 10211 may be configured to transmit the polarized light or reflect the polarized light. For example, the transflective film 10211 may be configured to transmit the polarized light in a first polarization direction and reflect the polarized light in a second polarization direction. Alternatively, the transflective film 10211 may be configured to reflect the polarized light in the first polarization direction and transmit the polarized light in the second polarization direction. The first polarization direction is perpendicular to the second polarization direction.

It is assumed that external environment light may be adjusted into the polarized light in the first polarization direction when passing through the polarizer 10215, and the liquid crystal layer 10213 is a liquid crystal cell in a twisted nematic (TN) mode. In addition, it is assumed that the transflective film 10211 may reflect the polarized light in the first polarization direction and transmit the polarized light in the second polarization direction.

If there is a voltage difference between the power signals supplied by the drive circuit 103 to the first electrode 10212 and the second electrode 10214 (for example, the potential of the power signal supplied by the drive circuit 103 to one of the first electrode 10212 and the second electrode 10214 is positive potential and the potential of the power signal supplied to the other electrode is negative potential, that is, an electrical field is applied), the liquid crystal molecules in the liquid crystal layer 10213 can tilt under action of the electrical field. In this case, external environment light passes through the polarizer 10215 to turn into the polarized light in the first polarization direction. The polarized light in the first polarization direction does not tilt when passing through the liquid crystal layer 10213. After being irradiated to the transflective film 10211, the polarized light in the first polarization direction may be reflected by the transflective film 10211, such that the electrochromic unit 1021 presents a specular state. In this case, the reflectivity of the electrochromic unit 1021 is relatively high, for example, may be greater than 50%.

If no voltage difference is detected between the power signals supplied by the drive circuit 103 to the first electrode 10212 and the second electrode 10214 (for example, the power signals supplied by the drive circuit 103 to the first electrode 10212 and the second electrode 10214 both have potential of 0 V, that is, no electrical field is applied), the liquid crystal molecules in the liquid crystal layer 10213 do not tilt. In this case, the external environment light becomes the polarized light in the first polarization direction after passing through the polarizer 10215. The polarized light in the first polarization direction is modulated into the polarized light in the second polarization direction after passing through the liquid crystal layer 10212. After being irradiated to the transflective film 10211, the polarized light in the second polarization direction may be transmitted by the transflective film 10211. The electrochromic unit 1021 may be in a non-opaque state. The reflectivity of the electrochromic unit 1021 is relatively low, and external environment light may be absorbed by the display panel 101. The electrochromic unit 1021 may produce an anti-glare effect (the non-opaque state of the electrochromic unit 1021 may also be referred to as an anti-glare state). In addition, if the display panel 101 displays an image at this time, the user can see content displayed on the display panel 101 through the electrochromic unit 1021 in the non-opaque state.

In the embodiments of the present disclosure, the control circuit 104 may be configured to supply a fourth control signal and a fifth control signal to the drive circuit 103. The drive circuit 103 may be configured to drive the electrochromic unit 1021 based on the fourth control signal to present a specular state and drive the electrochromic unit 1021 based on the fifth control signal to transmit the external environment light.

The drive circuit 103 may include a signal detector. The signal detector may determine, based on a control signal that the drive circuit 103 received from the control circuit 104, whether the received control signal is the fourth control signal or the fifth control signal. The drive circuit 103 may further drive the electrochromic unit 1021 based on the determined control signal.

In the embodiments of the present disclosure, the control circuit 104 may control the drive circuit 103 based on the light intensity of external environment light detected by the light intensity sensors. The drive circuit 103 may further adjust the state of the electrochromic unit 1021, such that the electrochromic unit 1021 presents a specular state or transmit external environment light.

In some embodiments, when the light intensity comparator in the control circuit 104 determines that the light intensity of external environment light is greater than or equal to the light intensity threshold, the control circuit 104 can supply the fifth control signal to the drive circuit 103, such that the drive circuit 103 drives the electrochromic unit 1021 based on the fifth control signal to transmit external environment light. When the light intensity comparator determines that the light intensity of external environment light detected by the light intensity sensors is less than the light intensity threshold, the control circuit 104 may supply the fourth control signal to the drive circuit 103, such that the drive circuit 103 drives the electrochromic unit 1021 to present a specular state based on the fourth control signal.

In the embodiments of the present disclosure, because each electrochromic unit 1021 in the electrochromic assembly 102 corresponds to one drive circuit 103, the control circuit 104 may control the drive circuit 103 based on the light intensity detected by the light intensity sensors in different areas to adjust the states of the electrochromic unit 1021 in the different areas.

In some embodiments, when the light intensity comparator determines that light intensity detected by the light intensity sensors disposed in an area of the electrochromic assembly 102 is greater than or equal to the light intensity threshold, the control circuit 104 may supply the fifth control signal to the drive circuit 103 corresponding to the electrochromic unit 1021 in the area. Alternatively, when the light intensity comparator determines that light intensity detected by the light intensity sensors disposed in an area of the electrochromic assembly 102 is less than the light intensity threshold, the control circuit 104 may supply the fourth control signal to the drive circuit 103 corresponding to the electrochromic unit 1021 in the area.

In some embodiments, the light intensity sensors may be a transparent solar panel, and can detect photo-generated current and convert solar energy into electrical energy, to supply energy to the display device 10.

In summary, this embodiment of the present disclosure provides a display device. An electrochromic assembly is attached to a light-exiting surface of a display panel in the display device. An electrochromic unit in the electrochromic assembly is driven by the drive circuit to present a specular state or transmit external environment light. When the electrochromic unit transmits external environment light, the display device displays an image normally, and when the electrochromic unit presents a specular state, the display device is used as a mirror to present an image of an object. That is, the display device may display an image and may be used as a mirror, to achieve relatively high flexibility.

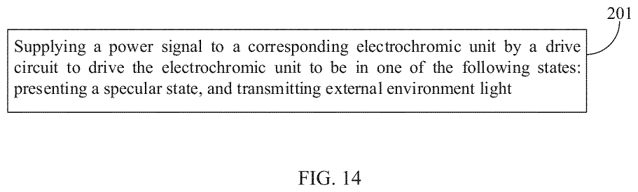

FIG. 14 is a flowchart of a method for driving a display device according to an embodiment of the present disclosure. The display device may be the display device 10 according to the above embodiment. The display device 10 includes a display panel 101, an electrochromic assembly 102, and at least one drive circuit 103. The electrochromic assembly 102 is attached to a light-exiting surface of the display panel 101. Referring to FIG. 1, the electrochromic assembly 102 includes at least one electrochromic unit 1021. The at least one electrochromic unit 1021 corresponds to the at least one drive circuit 103 one-to-one, and each drive circuit 103 is connected to one corresponding electrochromic unit 1021.

Referring to FIG. 14, the method may include the following steps.

In step 201, a power signal is supplied to the corresponding electrochromic unit by the drive circuit to drive the electrochromic unit to be in one of the following states: presenting a specular state, and transmitting external environment light.

In the embodiments of the present disclosure, the drive circuit 103 supplies a power signal to one corresponding electrochromic unit 1021, and the electrochromic unit 1021 adjusts its own state under action of the power signal, such that the display device 10 achieves different display effects.

In some embodiments, if the electrochromic unit 1021 presents a specular state, the electrochromic unit 1021 may be used as a mirror to present an image of an object, and the user cannot see the image displayed by the display panel 101 through the electrochromic unit 1021. If the electrochromic unit 1021 transmits external environment light (that is, the electrochromic unit 1021 presents a non-opaque state), the user can see the image displayed by the display panel 101 through the electrochromic unit 1021.

In summary, this embodiment of the present disclosure provides a method for driving a display device. A drive circuit supplies a signal to an electrochromic unit, such that the electrochromic unit presents a specular state or transmits external environment light. When the electrochromic unit transmits external environment light, the display device displays an image normally. When the electrochromic unit presents a specular state, the display device is used as a mirror to present an image of an object. That is, the display device may display an image and may be used as a mirror, to achieve relatively high flexibility.

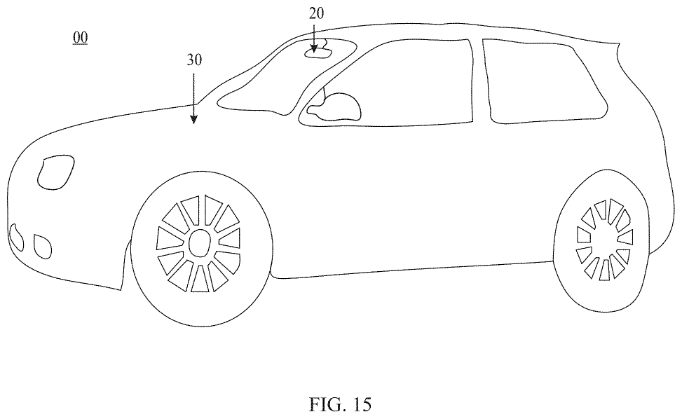

FIG. 15 is a schematic structural diagram of a vehicle according to an embodiment of the present disclosure. As can be seen from FIG. 15, a vehicle 00 may include a vehicle body 30 and a vehicle-mounted rear-view mirror 20 disposed on the vehicle body. The vehicle-mounted rear-view mirror 20 may be the display device 10 according to the above embodiment. The vehicle-mounted rear-view mirror 20 may include the display device according to the above embodiments.

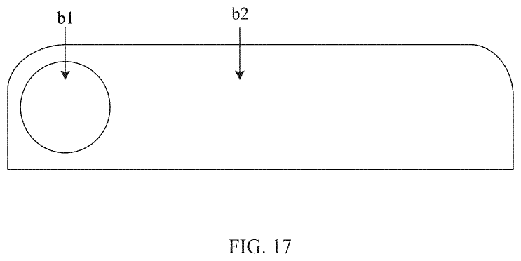

In the embodiments of the present disclosure, referring to FIG, 16, the electrochromic units 1021 may all be caused to transmit external environment light (may all be in a non-opaque state), such that all areas of the vehicle-mounted rear-view mirror 20 display a picture transmitted by a camera. Referring to FIG. 17, the electrochromic units 1021 in a relatively small area b1 may be caused to transmit external environment light, such that content such as incoming call information or speed that requires a relatively small display area is displayed on the vehicle-mounted rear-view mirror 20. In addition, the electrochromic units 1021 in another area b2 reflect the external environment light (a specular state), and this it is ensured that the vehicle-mounted rear-view mirror 10 presents a specular state in a relatively large area.

In addition, during nighttime driving, light rays radiated from the headlamps of a vehicle behind may be irradiated to the vehicle-mounted rear-view mirror 20, leading to interference to the driver's sight. In this case, the light rays radiated from the headlamps of the vehicle behind generate relatively intense glare in a partial area of the vehicle-mounted rear-view mirror 20 (the light intensity is relatively high in the partial area). In this case, to reduce the impact of light intensity, if all the electrochromic units 1021 in the electrochromic assembly 102 of the vehicle-mounted rear-view mirror 10 are adjusted to a non-opaque state, the mirror effect of the vehicle-mounted rear-view mirror 10 is affected. Therefore, to prevent the foregoing case, only the electrochromic units 1021 in the area where glare is generated may be adjusted to a non-opaque state, and the electrochromic units 1021 in another area remain in a specular state. In this way, glare generated in the partial area is suppressed, and it can be ensured that the specular state of the electrochromic units 1021 in another area is not affected.

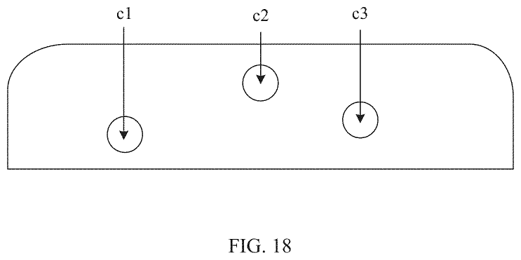

In the embodiments of the present disclosure, referring to FIG. 18, at a first moment t1, the light rays radiated from the headlamps of the vehicle behind generate relatively intense glare in a target area c1 of the vehicle-mounted rear-view mirror 20. In this case, the control circuit 104 may control the drive circuit 103 to adjust the electrochromic units 1021 in the target area c1 to a non-opaque state. Alternatively, at a second moment t2, the light rays radiated from the headlamps of the vehicle behind generate relatively intense glare in a target area c2 of the vehicle-mounted rear-view mirror 20. In this case, the control circuit 104 may control the drive circuit 103 to adjust the electrochromic units 1021 in the target area c2 to a non-opaque state. Further alternatively, at a third moment t3, the light rays radiated from the headlamps of the vehicle behind generate relatively intense glare in a target area c3 of the vehicle-mounted rear-view mirror 10. In this case, the control circuit 104 may control the drive circuit 103 to adjust the electrochromic unit 1021 of the target area c3 to a non-opaque state.

To be specific, the control circuit 104 in the vehicle-mounted rear-view mirror 20 may control the drive circuit 103 in real time based on light intensity to adjust the state of the electrochromic unit 1021, to ensure the driving safety.

Described above are merely exemplary embodiments of the present disclosure, and are not intended to limit the present disclosure. Within the spirit and principles of the disclosure, any modifications, equivalent substitutions, improvements, and the like are within the protection scope of the present disclosure.

What is claimed is:

1. A display device, comprising:
a display panel;
an electrochromic assembly, attached to a light-exiting surface of the display panel, and comprising at least one electrochromic unit; and
at least one drive circuit corresponding to the at least one electrochromic unit respectively, wherein each of the at least one drive circuit is connected to one corresponding electrochromic unit, and is configured to drive the electrochromic unit to be in one of the following states: presenting a specular state, and transmitting external environment light.

2. The display device according to claim 1, wherein an orthographic projection of the at least one drive circuit on the display panel is not overlapped with an orthographic projection of the electrochromic assembly on the display panel.

3. The display device according to claim 1, wherein the electrochromic unit comprises: a first electrode, a second electrode, and an electrolyte between the first electrode and the second electrode; wherein
the drive circuit is connected to the first electrode and the second electrode, and the drive circuit is configured to supply a first power signal to the first electrode and supply a second power signal to the second electrode; and
ions in the electrolyte are in one of the following states under action of the first power signal and the second power signal: moving, and remaining stationary.

4. The display device according to claim 3, wherein a material of the electrolyte comprises silver nitrate;
wherein silver ions in the silver nitrate are in one of the following states under action of the first power signal and the second power signal: moving toward the first electrode, moving toward the second electrode, and remaining stationary.

5. The display device according to claim 4, wherein a potential of the first power signal is higher than a potential of the second power signal; and
the silver ions move toward the second electrode under action of the first power signal and the second power signal.

6. The display device according to claim 5, wherein the first electrode and the second electrode are both transparent conductive glass coated with fluorine-doped tin oxide that has not been modified with titanium dioxide, and the silver ions move toward the second electrode, such that the electrochromic unit presents a specular state.

7. The display device according to claim 5, wherein the first electrode is transparent conductive glass coated with fluorine-doped tin oxide that has not been modified with titanium dioxide, the second electrode is titanium dioxide-modified transparent conductive glass coated with fluorine-doped tin oxide, and the silver ions move toward the second electrode, such that the electrochromic unit absorbs external environment light.

8. The display device according to claim 4, wherein a potential of the first power signal is lower than a potential of the second power signal; and
the silver ions move toward the first electrode under action of the first power signal and the second power signal.

9. The display device according to claim 8, wherein the first electrode is transparent conductive glass coated with fluorine-doped tin oxide that has not been modified with titanium dioxide, and the silver ions move toward the first electrode, such that the electrochromic unit presents a specular state.

10. The display device according to claim 4, wherein a potential of the first power signal is equal to a potential of the second power signal; and
the silver ions remain stationary under action of the first power signal and the second power signal, such that the electrochromic unit transmits external environment light.

11. The display device according to claim 3, Wherein the display panel comprises a first area, a second area surrounding the first area, and a third area surrounding the second area; wherein
the at least one electrochromic unit comprises: at least one first-type electrochromic unit, at least one second-type electrochromic unit, and at least one third-type electrochromic unit; and
an orthographic projection of the at least one first-type electrochromic unit on the display panel is within in the first area, an orthographic projection of the at least one second-type electrochromic unit on the display panel is within the second area, and an orthographic projection of the at least one third-type electrochromic unit on the display panel is within the third area.

12. The display device according to claim 11, wherein the first electrode is closer to the light-exiting surface of the display panel than the second electrode is;
a first-type drive circuit in the at least one drive circuit is configured to supply the first power signal to the first electrode in the first-type electrochromic unit and supply the second power signal to the second electrode in the first-type electrochromic unit within a first time period;
a second-type drive circuit in the at least one drive circuit is configured to supply the first power signal to the first electrode in the second-type electrochromic unit and supply the second power signal to the second electrode in the second-type electrochromic unit within a second time period; and
a third-type drive circuit in the at least one drive circuit is configured to supply the first power signal to the first electrode in the third-type electrochromic unit and supply the second power signal to the second electrode in the third-type electrochromic unit within a third time period, wherein the duration of the third time period is greater than the duration of the second time period, and the duration of the second time period is greater than the duration of the first time period.

13. The display device according to claim 12, wherein the first electrode and the second electrode are both transparent conductive glass coated with fluorine-doped tin oxide that has not been modified with titanium dioxide, and the potential of the first power signal is different from the potential of the second power signal.

14. The display device according to claim 12, wherein the first electrode is transparent conductive glass coated with fluorine-doped tin oxide that has not been modified with titanium dioxide, the second electrode is titanium dioxide-modified transparent conductive glass coated with fluorine-doped tin oxide, and a potential of the first power signal is lower than a potential of the second power signal.

15. The display device according to claim 3, wherein the display panel comprises a first area and a second area disposed on a side of the first area;
the at least one electrochromic unit comprises: at least one first-type electrochromic unit and at least one second-type electrochromic unit; and
an orthographic projection of the at least one first-type electrochromic unit on the display panel is within the first area, and an orthographic projection of the at least one second-type electrochromic unit on the display panel is within the second area.

16. The display device according to claim 15, wherein
a potential of the first power signal supplied by a first-type drive circuit in the at least one drive circuit to the first electrode of the first-type electrochromic unit is lower than a potential of the second power signal supplied to the second electrode of the first-type electrochromic unit; and
a potential of the first power signal supplied by a second-type drive circuit in the at least one drive circuit to the first electrode of the second-type electrochromic unit is equal to a potential of the second power signal supplied to the second electrode of the second-type electrochromic unit.

17. The display device according to claim 1, wherein the display device further comprises a control circuit;
the control circuit is connected to each drive circuit, and is configured to supply a first control signal, a second control signal or a third control signal to the drive circuit; and
the drive circuit is configured to:
drive the electrochromic unit based on the first control signal to present a specular state;
drive the electrochromic unit based on the second control signal to absorb external environment light; and
drive the electrochromic unit based on the third control signal to transmit external environment light.

18. The display device according to claim 17, wherein the display device further comprises a plurality of light intensity sensors connected to the control circuit;
the light intensity sensors are configured to detect the light intensity of external environment light; and
the control circuit is configured to:
supply the second control signal to the drive circuit if the light intensity is greater than or equal to a light intensity threshold; and
supply the third control signal to the drive circuit intensity is less than the light intensity threshold.

19. A driving method of a display device, wherein the display device comprises: a display panel; an electrochromic assembly, wherein the electrochromic assembly is attached to a light-exiting surface of the display panel, and comprises at least one electrochromic unit; and at least one drive circuit corresponding to the at least one electrochromic unit respectively, wherein each drive circuit is connected to one corresponding electrochromic unit; and
the method comprises:
supplying a power signal to the corresponding electrochromic unit by the drive circuit to drive the electrochromic unit to be in one of the following states: presenting a specular state, and transmitting external environment light.

20. A vehicle, comprising a vehicle body and a vehicle-mounted rear-view mirror disposed on the vehicle body, wherein the vehicle-mounted rear-view mirror comprises a display device;
and the display device comprises:
a display panel;
an electrochromic assembly, attached to a light-exiting surface of the display panel, and comprising at least one electrochromic unit; and
at least one drive circuit corresponding to the at least one electrochromic unit respectively, wherein each of the at least one drive circuit is connected to one corresponding electrochromic unit, and is configured to drive the electrochromic unit to be in one of the following states: presenting a specular state, and transmitting external environment light.
